(19) United States
(12) Patent Application Publication
(10) Pub. No.: US 2026/0047106 A1
(43) Pub. Date: Feb. 12, 2026

(54) INTEGRATED CIRCUIT PACKAGE WITH DRAM LOCATED WITHIN INTEGRATED COOLING CHANNELS

(71) Applicant: INTERNATIONAL BUSINESS MACHINES CORPORATION, ARMONK, NY (US)

(72) Inventors: Babar Khan, Ossining, NY (US); Mukta Ghate Farooq, Hopewell Junction, NY (US); John W. Golz, Hopewell Junction, NY (US); Aakrati Jain, Albany, NY (US); Diego Anzola, South Burlington, VT (US)

(21) Appl. No.: 18/797,958

(22) Filed: Aug. 8, 2024

(51) Int. Cl. H10B 80/00; H01L 23/00; H01L 23/13; H01L 23/15; H01L 23/467; H01L 25/18

(52) U.S. Cl. CPC H10B 80/00; H01L 23/13; H01L 23/467; H01L 24/96; H01L 23/15; H01L 24/48; H01L 24/85; H01L 25/18; H01L 2224/48145; H01L 2224/85986; H01L 2224/9512

(57) ABSTRACT

An apparatus including a stack of a plurality of substrates, wherein the stack includes a plurality of channels extending therethrough. The plurality of channels are configured to allow air to flow therethrough; a plurality of dynamic random-access memory (DRAM) chips. Respective ones of the plurality of DRAM chips are attached to one of the plurality of substrates and located within one of the plurality of channels. The apparatus also includes a plurality of processor chips located on an outer surface of the stack, and a plurality of wires electrically connecting the plurality of DRAM chips to the plurality of processor chips.

### BACKGROUND

The present disclosure generally relates to semiconductors, and more particularly to a semiconductor structure including packaging and thermal management structures.

With the onset of cloud computing, big data and other centralized high performance computing environments, system administrators are increasingly looking for new ways to pack as much functionality into as small a space as is practicable. This means packaging as much memory as possible, as close to the compute chip as possible. However, increasingly difficult component integration challenges, particularly with respect to packaging and cooling, present themselves when trying to maximize functionality and minimize space consumption.

### SUMMARY

According to some embodiments of the disclosure, there is provided an apparatus including a stack of a plurality of substrates, wherein the stack includes a plurality of channels extending therethrough. The plurality of channels are configured to allow air to flow therethrough; a plurality of dynamic random-access memory (DRAM) chips. Respective ones of the plurality of DRAM chips are attached to one of the plurality of substrates and located within one of the plurality of channels. The apparatus also includes a plurality of processor chips located on an outer surface of the stack, and a plurality of wires electrically connecting the plurality of DRAM chips to the plurality of processor chips.

According to some embodiments of the disclosure, there is provided a system for thermal management. The system includes an integrated circuit (IC) package and at least one heat dissipating device located adjacent at least one side of the IC package. The IC package can include a stack of a plurality of substrates. The stack includes a plurality of channels extending therethrough. The plurality of channels are configured to allow air to flow therethrough. The stack also includes a plurality of dynamic random-access memory (DRAM) chips. Respective ones of the plurality of DRAM chips are attached to one of the plurality of substrates and located within one of the plurality of channels. The stack also includes a plurality of processor chips located on an outer surface of the stack, and a plurality of wires electrically connecting the plurality of DRAM chips to the plurality of processor chips.

According to some embodiments of the disclosure, there is provided a method of fabricating an integrated circuit (IC) package. The method includes: providing a plurality of substrates, wherein the plurality of substrates have a first side and a second side; forming a plurality of wires within the first side of the plurality of substrates; forming trenches within the second side of the plurality of substrates; attaching a plurality of dynamic random-access memory (DRAM) chips to the plurality of wires on the first side of the plurality of substrates; stacking the plurality of substrates such that the DRAM chips on one of the plurality of substrates is located within the trenches on another adjacent one of the plurality of substrates in order to form a plurality of cooling channels around the plurality of DRAM chips adapted to provide air flow to the plurality of DRAM chips within a stack formed by the stacking; attaching a plurality of processor chips to an outer surface of the stack; and electrically connecting the plurality of processor chips to the plurality of DRAM chips.

The above summary is not intended to describe each illustrated embodiment or every implementation of the present disclosure.

### BRIEF DESCRIPTION OF THE DRAWINGS

The drawings included in the present application are incorporated into, and form part of, the specification. They illustrate embodiments of the present disclosure and, along with the description, serve to explain the principles of the disclosure. The drawings are only illustrative of certain embodiments and do not limit the disclosure.

FIG. 1 illustrates a perspective view of an integrated circuit (IC) package, in accordance with embodiments of the present disclosure.

FIG. 2 illustrates a side, cross-sectional view of a step in the fabrication of the IC package of FIG. 1, in accordance with embodiments of the present disclosure.

FIG. 3 illustrates a side, cross-sectional view of a step in the fabrication of the IC package of FIG. 1, in accordance with embodiments of the present disclosure.

FIG. 4 illustrates a side, cross-sectional view of a step in the fabrication of the IC package of FIG. 1, in accordance with embodiments of the present disclosure.

FIG. 5 illustrates a side, cross-sectional view of a step in the fabrication of the IC package of FIG. 1, in accordance with embodiments of the present disclosure.

FIG. 6 illustrates side, a cross-sectional view of a step in the fabrication of the IC package of FIG. 1, in accordance with embodiments of the present disclosure.

FIG. 7 illustrates a side, cross-sectional view of a step in the fabrication of the IC package of FIG. 1, in accordance with embodiments of the present disclosure.

FIG. 8 illustrates a top-down view of a substrate taken from a mounting side for DRAM chips, in accordance with embodiments of the present disclosure.

FIG. 9 illustrates a side, cross-sectional view of a step in the fabrication of the IC package of FIG. 1, in accordance with embodiments of the present disclosure.

While the disclosure is amenable to various modifications and alternative forms, specifics thereof have been shown by way of example in the drawings and will be described in detail. It should be understood, however, that the intention is not to limit the disclosure to the particular embodiments described. On the contrary, the intention is to cover all modifications, equivalents, and alternatives falling within the spirit and scope of the disclosure.

### DETAILED DESCRIPTION

Aspects of the present disclosure relate generally maximizing memory as close to a compute chip as possible, while still providing thermal regulation of semiconductors. More particularly, the present disclosure provides an integrated circuit (IC) package with dynamic random-access memory (DRAM) located within integrated cooling channels with compute chips placed on an outer surface or surfaces of the IC package. While the present disclosure is not necessarily limited to such applications, various aspects of the disclosure can be appreciated through a discussion of various examples using this context.

IC packaging is a part of a semiconductor manufacturing process that involves enclosing one or more ICs (or semiconductor dies) in a protective and often functional package. The packaging can serve several purposes, including providing protection from environmental factors, heat dissipation, and can include other features such as signal conditioning or power delivery.

In high performance computing systems, one of the primary goals can be to package as much memory as possible close to each computing chip (such as a logic chip). “Close” can be characterized as near physical proximity to processing circuits such as to provide the highest possible data bandwidth, lowest possible data request latency, and lowest possible energy dissipation per transfer of data bits between the memory and the processing circuits. One way to achieve this with 2.5D IC packaging is to add high density and high bandwidth memory (HBM) close to the computing chips. 2.5D IC packaging involves placing two or more active semiconductor dies side by side on a silicon interposer.

Embodiments of the present disclosure include can also achieve packing or packaging in memory in an integrated circuit (IC) package that can include many commercial DRAM chips. The DRAM chips need to remain cooled to a specific range of temperatures in order to function properly. In the IC package, integrated cooling channels can be included that are located around the DRAM chips and can allow cooling air to flow over the DRAM chips. Hear dissipation from the DRAM chips can occur. Thermal management of the DRAM chips can be possible. Electrical wiring can connect the DRAM chips to logic chips that can be located on an outer surface of the IC package where the logic chips can be cooled by other methods or devices.

Embodiments of the present disclosure can include a multidimensional IC package consisting of DRAM chips with built in cooling, without through-silicon vias (TSVs), using commercial DRAM chips that can be embedded in the IC package and electrically connected to logic chips on a top, a bottom, or sides of the IC package. The IC package can be fabricated with silicon substrates, but alternatively, the IC package can be built with glass substrates that allow a coefficient of thermal expansion (CTE) to be tailored according to the needs of the IC package.

Embodiments of the present disclosure can include a multidimensional IC package that includes a glass cube for chiplet integration with built-in cooling. The glass cube can provide effective cooling channels around memory chips (such as DRAM chips), and without the presence of through vias or TSVs.

Embodiments of the present disclosure can include an IC package formed without through vias. The IC package includes stacked commercial DRAM chips that are attached and electrically connected to substrates, which have integrated cooling channels and electrical wiring that connects the DRAM chips to compute chips attached at a top or bottom of the IC package and allows the DRAM chips to be cooled. The IC package can be fabricated with glass substrates. The substrates can include the attached commercial DRAM chips, integrated cooling and wiring. The IC package can be formed by stacking the substrates with attached commercial DRAM chips that are also attached to wiring that connects the DRAM chips electrically to compute chips on a top or bottom of the IC package. The IC package can include electrical wiring connections on the top and/or bottom that allow the compute chips on the top and/or bottom to be electrically connected to vertical wiring from the embedded commercial DRAM chips. In addition, other circuit components, such as capacitors and regulators can be provided inside the IC package to enable the overall system design as well as to provide power regulation near the compute chips.

Embodiments of the present disclosure can include an apparatus including: a stack of a plurality of substrates, wherein the stack includes a plurality of channels extending therethrough, wherein the plurality of channels are configured to allow air to flow therethrough; a plurality of dynamic random-access memory (DRAM) chips, wherein respective ones of the plurality of DRAM chips are attached to one of the plurality of substrates and located within one of the plurality of channels; a plurality of processor chips located on an outer surface of the stack; and a plurality of wires electrically connecting the plurality of DRAM chips to the plurality of processor chips. The plurality of substrates can be glass substrates. The processor chips can be logic chips. The stack can be arranged on its side, and the plurality of substrates can extend vertically within the stack. The plurality of wires can extend vertically from the plurality of DRAM chips to the plurality of processor chips. The apparatus can also include: a plurality of connections located on the outer surface of the stack and configured to electrically connect the plurality of processor chips to the plurality of wires.

Embodiments of the present disclosure can include a system for thermal management. The system includes an integrated circuit (IC) package and at least one heat dissipating device located adjacent at least one side of the IC package. The IC package can include a stack of a plurality of substrates. The stack includes a plurality of channels extending therethrough. The plurality of channels are configured to allow air to flow therethrough. The stack also includes a plurality of dynamic random-access memory (DRAM) chips. Respective ones of the plurality of DRAM chips are attached to one of the plurality of substrates and located within one of the plurality of channels. The stack also includes a plurality of processor chips located on an outer surface of the stack, and a plurality of wires electrically connecting the plurality of DRAM chips to the plurality of processor chips. The system can also include an apparatus adapted to force air through the plurality of channels. The at least one heat dissipating device can be a heat sink. The IC packages can include a plurality of connections located on the outer surface of the stack and configured to electrically connect the plurality of processor chips to the plurality of wires.

Embodiments of the present disclosure can include a method of fabricating an integrated circuit (IC) package. The method includes: providing a plurality of substrates, wherein the plurality of substrates have a first side and a second side; forming a plurality of wires within the first side of the plurality of substrates; forming trenches within the second side of the plurality of substrates; attaching a plurality of dynamic random-access memory (DRAM) chips to the plurality of wires on the first side of the plurality of substrates; stacking the plurality of substrates such that the DRAM chips on one of the plurality of substrates is located within the trenches on another adjacent one of the plurality of substrates in order to form a plurality of cooling channels around the plurality of DRAM chips adapted to provide air flow to the plurality of DRAM chips within a stack formed by the stacking; attaching a plurality of processor chips to an outer surface of the stack; and electrically connecting the plurality of processor chips to the plurality of DRAM chips. The method can also include placing the stack on its side, wherein the plurality of substrates extend vertically within the stack, wherein the plurality of processor chips are attached to a top side or a bottom side of the stack.

An advantage of disclosed embodiments of the present disclosures can be that a large amount of memory (such as DRAM) can be packed or located close to compute chips (such as logic chips). In addition, another advantage can be that embodiments include a relatively simple package that does not include any TSVs while at the same time keeping operating temperatures of the memory (such as DRAM) within specifications. For example, even by using conventional 16 gigabyte (gb) commodity DRAM, over a terabyte (TB) of memory can be included inside the disclosed IC package. The IC package can also include a large number of vertical wires in each plane allowing for large bandwidth. If the IC package is made of glass, for example, a CTE of the IC package can be advantageously tailored by using glass with CTE in a desired, preferable range. Some process steps can also be simplified if glass is used, which can be advantageous in that it can reduce costs and complexity. However, the structure and associated processes for forming the structure can be replicated on silicon substrates using processes that are well known in semiconductor technology.

Compared to high bandwidth memory (HBM), the disclosed IC package (or “cube”) can advantageously cost less to produce. The IC package can include standard DRAM and can be made of silicon, glass or organic laminate. Speed of the disclosed IC package can be advantageously higher than HBM, as the IC package can use standard DRAM that has an input/output (I/O) width of 16 bits and parallel connections to multiple DRAM chips can enable much higher bandwidth. Bandwidth or capacity of the IC package can be traded off with speed, for example, by using more granular DRAMs for the IC package and levels can be found where the IC package can perform better than a 4 HBM solution both for capacity and bandwidth. The IC package can have more effective DRAM layers than HBM. In addition, the IC package can provide greater flexibility to a system designer, as the system designer can expand or contract the IC package size as needed, using commercially available DRAM chips as compared to an expensive HBM solution that cannot be granularized.

Embodiments of the present disclosure can also advantageously increase data bandwidth between memory chips and a processor by increasing a number of vertical connecting wires. The embodiments can also include signaling speed (data rate per wire) with low power loss and reduced capacitive and inductive coupling. Since additional data line connections are possible, high granularity memory can be advantageously designed to improve latency and random-access times. Advantageously, data bandwidth between the memory and the processing circuits (or processors) increases with the number of connecting wires as well as the signaling speed (data rate per wire). In practice, interconnect density can limit the number of connecting wires. A module laminate can, for example, fanout from chip bump to circuit board ball grid array (BGA). Similarly, wire length can constrain signaling speed due to capacitive coupling to adjacent wires and surrounding environment. Thus, connecting memory using the highest density wiring paths and shortest wire length, as in some embodiments disclosed herein, can maximize data bandwidth.

Energy per bit depends on signal wire capacitance and signaling voltage level. If termination schemes are employed, matching loads also introduce power loss. Unterminated single-ended signaling consumes the least energy per data bit but requires low capacitive and inductive coupling to operate without transmission error, which implies shortest wire lengths. In the IC package, the wiring between the DRAM chips can be far apart as the wiring pitches can be large. In addition, if the IC package is made from glass substrates, parasitic capacitances can be further reduced. This means that effective parasitic capacitance per unit length of wiring in the IC package can be minimized, which can enable higher speeds.

Data latency can also be affected by interconnect density. Given fewer connections, memory data arrays are often designed with large word lines and low granularity in order to support a “burst” mode. Higher memory granularity can be enabled by the IC package, which means that many more memory bits can be accessed in parallel, which can enable larger bandwidth for the same memory access mode. However, if additional data line connections are possible, high granularity memory can be designed to improve latency and random-access times. A system designer can also add another chip or chips (such as logic chips with memory) to the IC package that can provide an interface between the DRAM and the compute chip(s) to maximize system performance if needed. The additional chip can be located close to the compute chip, either on the inside of the IC package or on the surface depending on power consumption and system requirements.

It will be readily understood that the components of the present embodiments, as generally described and illustrated in the Figures herein, can be arranged and designed in a wide variety of different configurations. Thus, the following detailed description of the embodiments of the apparatus, system, method, and computer program product of the present embodiments, as presented in the Figures, is not intended to limit the scope of the embodiments, as claimed, but is merely representative of selected embodiments.

Reference throughout this specification to “a select embodiment,” “one embodiment,” or “an embodiment” means that a particular feature, structure, or characteristic described in connection with the embodiment is included in at least one embodiment. Thus, appearances of the phrases “a select embodiment,” “in one embodiment,” or “in an embodiment” in various places throughout this specification are not necessarily referring to the same embodiment. It should be understood that the various embodiments can be combined with one another, and that any one embodiment can be used to modify another embodiment.

As used in this application and in the claims, the singular forms “a,” “an,” and “the” include the plural forms unless the context clearly dictates otherwise. Additionally, the term “includes” means “comprises.”

The term “semiconductor die” generally refers to a die having integrated circuits or components, data storage elements, processing components, and/or other features manufactured on semiconductor substrates. For example, semiconductor dies can include integrated memory circuitry and/or logic circuitry. Semiconductor dies and/or other features in semiconductor die packages can be said to be in “thermal contact” with one another if the two structures can exchange energy through heat via, for example, conduction, convection and/or radiation. A person skilled in the relevant art will also understand that the technology can have additional embodiments, and that the technology can be practiced without several of the details of the embodiments described below with reference to the figures.

As used herein, the terms “vertical,” “lateral,” “upper,” “lower,” “up,” “down,” “upstream,” and “downstream” can refer to relative directions or positions of features in the semiconductor die assemblies in view of the orientation shown in the Figures. For example, “upper” or “uppermost” can refer to a feature positioned closer to the top of a page than another feature. These terms, however, should be construed broadly to include semiconductor devices having other orientations, such as inverted or inclined orientations where top/bottom, over/under, above/below, up/down and left/right can be interchanged depending on the orientation.

The semiconductor devices and methods for forming the same, in accordance with embodiments of the present disclosure, can be employed in applications, hardware, and/or electronic systems. Suitable hardware and systems for implementing embodiments of the invention can include, but are not limited to, personal computers, communication networks, electronic commerce systems, portable communications devices (e.g., cell and smart phones), solid-state media storage devices, functional circuitry, etc. Systems and hardware incorporating the semiconductor devices are contemplated embodiments of the invention. Given the teachings of embodiments of the invention provided herein, one of ordinary skill in the art will be able to contemplate other implementations and applications of embodiments of the invention.

However, the concepts presented are readily adapted to use with other types of coolant. For example, the coolant can comprise a glycol solution, a brine, a fluorocarbon liquid, a liquid metal, or other similar coolant, or refrigerant, while still maintaining the advantages and unique features of the present disclosure.

It is to be understood that the present disclosure will be described in terms of a given illustrative architecture; however, other architectures, structures, substrate materials and process features and steps/blocks can be varied within the scope of the present disclosure. It should be noted that certain features cannot be shown in all figures for the sake of clarity. This is not intended to be interpreted as a limitation of any particular embodiment, or illustration, or scope of the claims.

The illustrated embodiments will be best understood by reference to the drawings, where like parts are designated by like numerals throughout. The following description is intended only by way of example, and simply illustrates certain selected embodiments of devices, systems, and processes that are consistent with the embodiments as claimed herein.

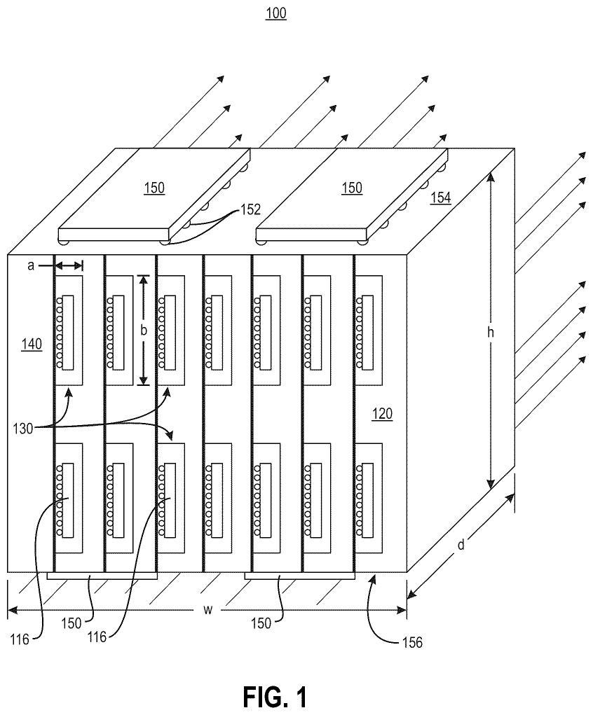

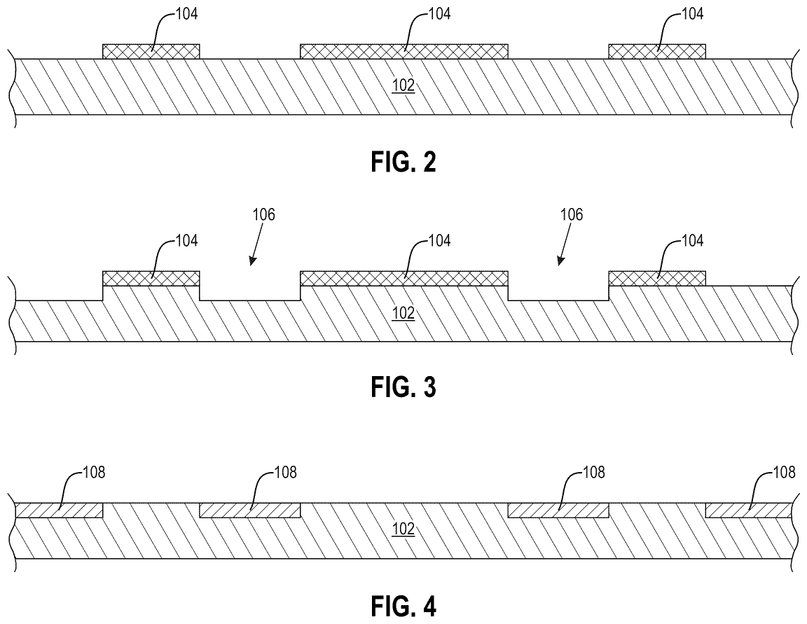

FIG. 1 illustrates a perspective view of an IC package 100, in accordance with embodiments of the present disclosure. Fabrication of the IC package 100 will be described herein below with regards to subsequent figures. The IC package 100 can have a cube Uke shape (as shown) formed from a plurality of the substrate/DRAM chip combination components 120 that are stacked and attached together, such as shown in the figure. A plurality of DRAM chips 116 can be located within and along each of a plurality of cooling channels 130 that extend through the IC package 100. Metal wires (not shown) can attach the plurality of DRAM chips 116 to processor chips 150 (or “compute chips”) that are located on the outside of the IC package, such as on a top 154 and/or a bottom 156 of the IC package 100. Heat produced by the DRAM chips 116 can be dissipated via air (indicated, for example, by arrows in the figure) moved through the cooling channels 130. An apparatus (e.g., a fan) can be used that is adapted to force air through the cooling channels 130 in order to cool the DRAM chips 116. The IC package 100 will be described herein in more detail after fabrication of the IC package is detailed below with regards to FIGS. 2-9.

FIG. 2 illustrates a side, cross-sectional view of a step in the fabrication of the IC package 100 of FIG. 1, in accordance with embodiments of the present disclosure. A substrate 102 is shown with portions of a first masking layer 104 (or film) that has been patterned atop the substrate 102 as desired. The substrate 102 can be made of a glass, silicon (Si) or quartz material, for example. Using microlithography, for example, the first masking layer 104 can be created over the substrate 102, as shown, in a desired pattern.

FIG. 3 illustrates a side, cross-sectional view of a step in the fabrication of the IC package of FIG. 1, in accordance with embodiments of the present disclosure. After the step shown in FIG. 2, for example, an etching process, such as wet etching, reactive ion etching (RIE), etc., can be used to create a plurality of trenches 106 in the substrate 102 in locations where the first masking layer 104 is not located atop the substrate 102.

FIG. 4 illustrates a side, cross-sectional view of a step in the fabrication of the IC package 100 of FIG. 1, in accordance with embodiments of the present disclosure. After the step shown in FIG. 3, for example, the masking layer 104 (as shown in FIG. 3) can be removed, and a layer or film of metal material (or “metallization layer”) can be applied atop the substrate 102, including being applied in the plurality of trenches 106. The metal material can be, for example, copper (Cu) or tungsten (W), but other suitable metals are also contemplated. The metal material can also be made of multiple layers of metal that can solve any metal adhesion issues that may arise. After the metal layer is applied, a chemical mechanical polishing (CMP) process can be performed in order to level the layer of metal material, while leaving behind metal in the trenches (trenches 106 in FIG. 3) that form a plurality of metal wires 108 within the substrate 102.

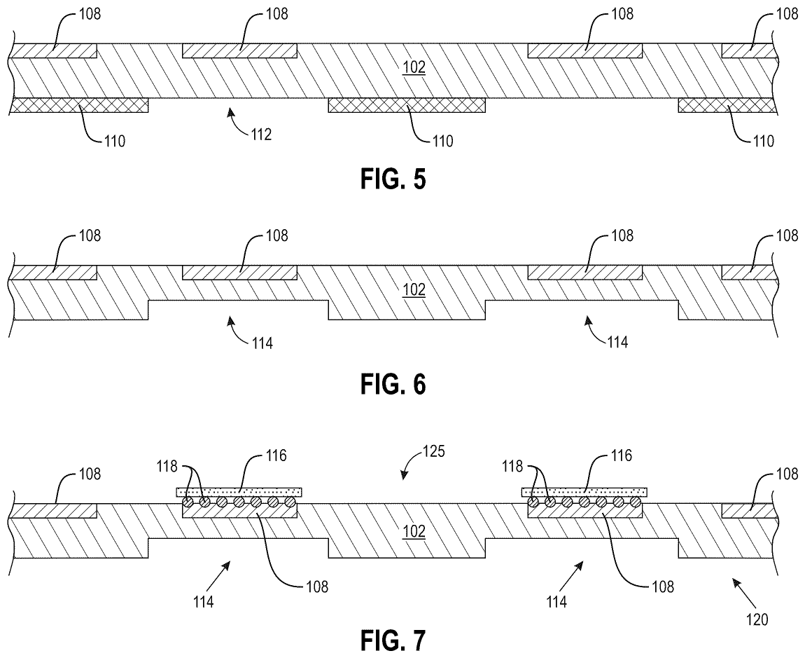

FIG. 5 illustrates a side, cross-sectional view of a step in the fabrication of the IC package 100 of FIG. 1, in accordance with embodiments of the present disclosure. After the step shown in FIG. 4, the structure that includes the substrate 102 and the metal wires 108 can be flipped (as shown in FIG. 6) and a second masking layer 110 can be applied, using microlithography, for example, on a backside 112 of the substrate 102, as shown, in a desired pattern.

FIG. 6 illustrates a side, cross-sectional view of a step in the fabrication of the IC package 100 of FIG. 1, in accordance with embodiments of the present disclosure. After the step shown in FIG. 5, an etching process, such as wet etching, RIE, etc., can be used to create a plurality of deep or large trenches 114 in the substrate 102 in locations where the second masking layer 110 (shown in FIG. 5) was not previously located on the substrate 102. The second masking layer 110 (shown in FIG. 5) has been removed. The plurality of large trenches 114 are left open or empty. A purpose of the plurality of large trenches 114, as shown in and described with regards to other figures, can be to form a plurality of cooling channels (the cooling channels 130 in FIG. 1) that can allow air to be moved therethrough the plurality of cooling channels (the cooling channels 130 in FIG. 1), when the IC package 100 (as shown in FIG. 1) is assembled.

FIG. 7 illustrates a side, cross-sectional view of a step in the fabrication of the IC package 100 of FIG. 1, in accordance with embodiments of the present disclosure. After the step shown in FIG. 6, a plurality of DRAM chips 116 can be attached to each of the plurality of metal wires 108 by for example, using copper to copper binding or hybrid bonding. Alternatively, a plurality of connections 118 can be used to bind the DRAMS chips 116 to the substrate 102. The connections 118 can be “micro-balls,” as shown, that can bond and bring each of the DRAM chips 116 closer to the substrate 102. Micro-balls can be very small ball-shaped connectors that are made of metal, for example. Other methods of bonding can be used, such as hybrid bonding can be used to connect the DRAM chips 116 to the substrate 102. If hybrid bonding is used, then the connections 118 may not resemble balls and can instead be plugs within the DRAM chips 116 or substrate 102, for example, which can allow the substrate 102 and the DRAM chips 116 to be located closer together. A lower profile can result using hybrid bonding, for example, which can be beneficial to the IC package 100. Other suitable methods for bonding the DRAM chips 116 to the metal wires 108 are also contemplated.

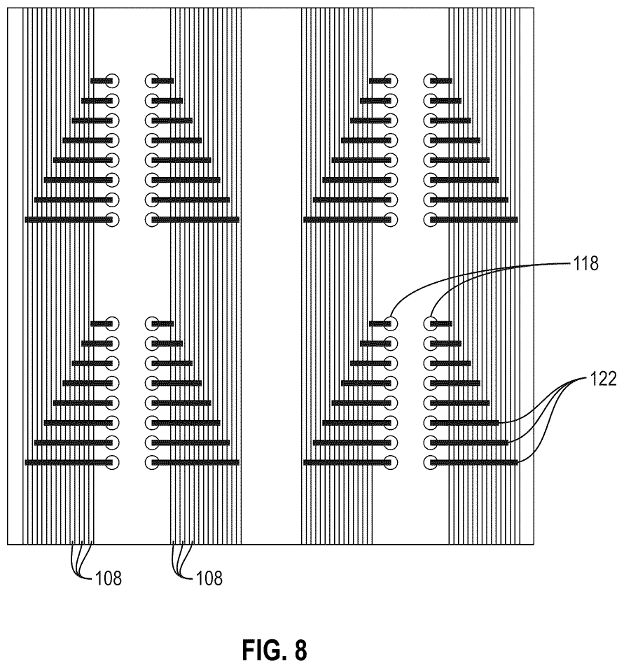

Using photolithography processes, the connections 118 can be joined to the metal wires 108. As shown in FIGS. 4-7, the metals wires 108 appear as an “island” in the cross-sectional, side view. However, FIG. 8, discussed below, provides a top-down view of the substrate 102 from a mounting side 125 (mounting side 125 shown in FIG. 7) for the DRAM chips 116, and illustrates how the connections 118 can be connected to the metal wires 108. The structure assembled and shown in FIG. 7 is referred to below as a substrate/DRAM chip combination component 120.

Although the DRAM chips 116 are shown and described herein with regards to the IC package 100, other memory chips or components are contemplated by the present disclosure. Other memory chips or components can be used within the IC package 100 that can also generate heat during their use that needs to be dissipated or reduced.

FIG. 8 illustrates a top-down view of the substrate 102 taken from the mounting side 125 (shown in FIG. 7) for the DRAM chips 116, in accordance with embodiments of the present disclosure. Using back end-of-line (BEOL) processing, a layer of metal can be created within a plurality of vias (not shown) that are connected by other vias (not shown) to the connections 118. As a result, each of the metal wires 108 are connected to one connection 118 on each of the DRAM chips (not shown in the figure). There are also a plurality of metal wires 122 extending between the connections 118 and the metal wires 108. Standard processing steps can be used in semiconductor fabrication to form the structure shown in FIG. 8.

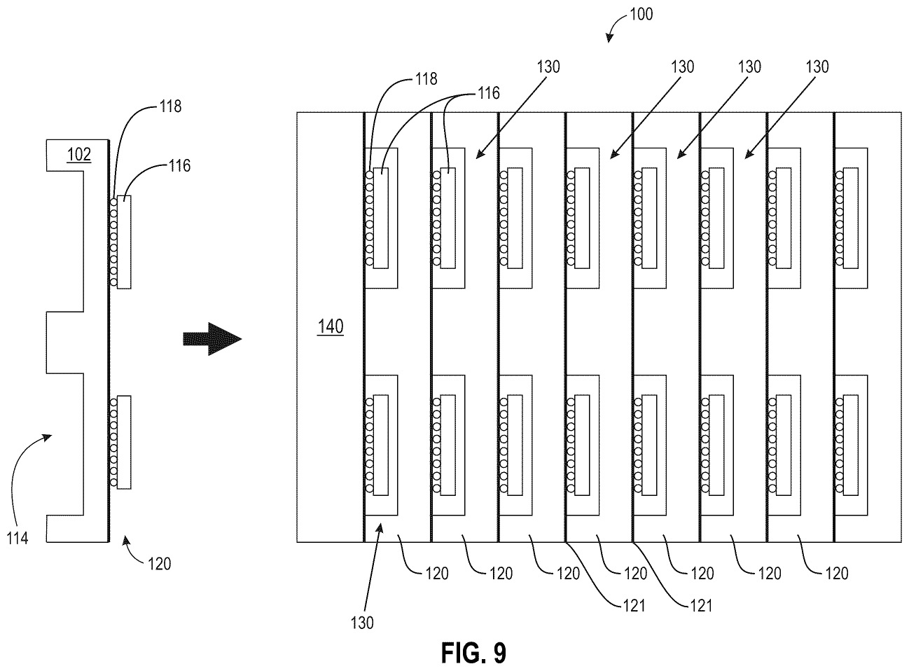

FIG. 9 illustrates a side, cross-sectional view of a step in the fabrication of the IC package of FIG. 1, in accordance with embodiments of the present disclosure. The figure shows one of the substrate/DRAM chip combination components 120 (bottom), as shown formed in FIG. 7, and an arrow to a result of a plurality of the substrate/DRAM chip combination components 120 and one alternative substrate/DRAM chip combination layer 140 stacked on top of one another. The multiple substrate/DRAM chip combination components 120, in the stack shown, are lined up such that each large trench 114 (from FIG. 7) surrounds one DRAM chip 116 on another adjacent one of the substrate/DRAM chip combination components 120, which forms the plurality of cooling channels 130 surrounding the DRAM chips 116. The multiple substrate/DRAM chip combination components 120 can be joined by direct wafer to wafer bonding with or without an intermediate layer, such as hybrid bonding. In addition, the wafers can be bonded together using adhesive wafer bonding resulting in a layer of adhesive 121.

The stack of the multiple substrate/DRAM chip combination components 120 is shown turned on its side. The metal wires 108 (the metal wires 108 shown in FIG. 8) then run vertically in the resulting IC package 100 of FIG. 1 (not visible in FIG. 1). The DRAM chips 116 can be independently addressed by separate wires or they can be addressed in parallel as shown in FIG. 8 depending on system design. An alternative substrate/DRAM chip combination layer 140 is added to an end of the assembled IC package 100 (also shown in FIG. 1) in order to form a cube shape.

Referring back to the IC package 100 shown in FIG. 1, the IC package 100 has a cube shape formed from the plurality of the substrate/DRAM chip combination components 120 that are stacked and attached together. The plurality of DRAM chips 116 can be located within and along each of a plurality of cooling channels 130 that extend through the IC package 100. Only one DRAM chip 116 is visible in the figure in each cooling channel 130. However, there can be multiple DRAM chips 116 within each cooling channel 130 extending back into the plane of the page of the figure. Heat produced by the DRAM chips 116 can be dissipated via cooling air (indicated, for example, by arrows in the figure) moved through the cooling channels 130. Additional metal wires (not shown) can attach the plurality of DRAM chips 116 to the processor chips 150 (that are located on the outside of the IC package 100, such as on the top 154 and/or the bottom 156 of the IC package 100. Any suitable number of the processor chips 150 can be located on the top 154 and/or the bottom 156 of the IC package 100. The processor chips 150 have connections 152 that connect to the top 154 and bottom 156 of the IC package 100, and that connect to metal lines (not visible) within the IC package 100 as well. Such additional metal wires (not shown) can be made using standard deposition, etching, metallization, etc., processes and direct write lithographic tools.

The IC package 100 allows multiple of the DRAM chips 116 to be connected with metal wires to each one of the processor chips 150. This is advantageous in order to provide a large amount of memory near each of the processor chips 150. Although the DRAM chips 116 can have low power, the DRAM chips 116 can create a considerable amount of heat. The cooling channels 130 (only a few of cooling channels 130 are marked with numbers and arrows in figure) that are created in the IC package 100 around the DRAM chips 116 allow for air cooling of the DRAM chips 116 to keep the DRAM chips 116 within operating temperatures that meet specifications of the DRAM chips 116.

The IC package 100 can be used with other heat dissipating components that are not shown in the figures. For example, a heat sink could be placed on the top 154 of the IC package 100 and/or the bottom 156. The heat sink could allow air to cool the processor chips 150. Alternatively, a fluid-cooling component, or other air-cooling components, can be located adjacent the processor chips 150, for example, in order to cool the processor chips 150.

The two sides of the IC package 100 in FIG. 1 are shown as sealed. Alternatively, the sides of the cube of the IC package 100 can include additional ones of the processor chips 150. Additionally, the IC package 100 can include additional cooling components on the sides. The IC package 100 can, for example, include up to four (4) sides accessible for hotter chips, such as the processor chips 150. Multiple cooling components can be used in order to col any of the processor chips 150 on the IC package 100.

An advantage of the IC package 100 is that TSVs are not included in the IC package 100 and are not required for performance. TSVs are expensive to include in an IC package, for example. A lack of TSVs can save money in fabricating the IC package 100, for example. In addition, money can be saved by using commercially available DRAM chips.

Another advantage of the IC package 100 is that the design allows for a lot of memory (e.g., the DRAM 116) to be packed close to the processor chips 150, while providing efficient cooling of the processor and the memory chips.

The IC package 100 of FIG. 1 can have any suitable dimensions that allow its functional incorporation into devices. The dimensions also should not allow a significant time delay between the DRAM chips 16 and the processor chips 150. For example, the IC package can be a cube with a width (w) and a height (h) of 1 inch (2.54 centimeters (cm)) each or 1.5 inch (3.81 cm) each. An example of ranges for the dimensions can be a width (w) of one (1) cm to five (5) cm, a length (1) of one (1) cm to five (5) cm, and a height (h) of 0.5 cm to five (5) cm.

The IC package 100 can, for example, be a cube-shaped structure with dimensions of 24 millimeters (mm) height (“h” in FIG. 1) by 22 mm width (“w” in FIG. 1) by 20 mm depth (“d” in FIG. 1). The IC package 100 can include fifty (50) units, or substrate/DRAM chip combination components 120, and one hundred (100) DRAM chips 116. The length of the cooling channels 130, therefore, is 20 mm (the “d” dimension in FIG. 1). The height of the cooling channels 130, as indicated by “a” in FIG. 1, can be 175-350 micrometers (μ), for example. The width of the cooling channels 130, as indicated by “b” in FIG. 1, can be 10-11 mm, for example. Other suitable dimensions are, however, contemplated by the disclosure. There can be, for example, two hundred (200) copper wires running in the “h” direction in each unit, or substrate/DRAM chip combination component 120, at one hundred (100) um pitch, or more wires at a smaller pitch. The wire thickness can be as much as half the pitch, for example.

The IC package 100 can also include other components that are not shown in the figure. For example, capacitors and regulators can be included in the IC package. Alternatively, or additionally, the IC package 100 can include one or more logic chips with memory that can be located near the compute chips 150.

The present disclosure also includes a method of fabricating the IC package 100. The method includes an operation of providing a plurality of substrates 102 that have a first side and a second side. The method also includes an operation of forming a plurality of wires 108 within the first side of the plurality of substrates 102. A further operation includes forming trenches 114 within the second side of the plurality of substrates 102. Another operation includes attaching a plurality of dynamic random-access memory (DRAM) chips 116 to the plurality of metal wires 108 on the first side of the plurality of substrates 102. Yet another operation includes stacking the plurality of substrates 102 such that the DRAM chips 116 on one of the plurality of substrates 102 is located within the trenches 114 on another adjacent one of the plurality of substrates in order to form a plurality of cooling channels 130 around the plurality of DRAM chips 116 adapted to provide air flow to the plurality of DRAM chips 116 within a stack formed by the stacking. Additional operations include attaching a plurality of processor chips 150 to an outer surface of the stack, and electrically connecting the plurality of processor chips 150 to the plurality of DRAM chips 116. The method can also include an operation including placing the stack on its side. The plurality of substrates 102 can extend vertically within the stack. The plurality of processor chips 150 can be attached to a top side or a bottom side of the stack.

For purposes of this description, certain aspects, advantages, and novel features of the embodiments of this disclosure are described herein. The disclosed processes, and systems should not be construed as being limiting in any way. Instead, the present disclosure is directed toward all novel and nonobvious features and aspects of the various disclosed embodiments, alone and in various combinations and sub-combinations with one another. The processes, and systems are not limited to any specific aspect or feature or combination thereof, nor do the disclosed embodiments require that any one or more specific advantages be present, or problems be solved.

Although the operations of some of the disclosed embodiments are described in a particular, sequential order for convenient presentation, it should be understood that this manner of description encompasses rearrangement, unless a particular ordering is required by specific language set forth below. For example, operations described sequentially can in some cases be rearranged or performed concurrently. Moreover, for the sake of simplicity, the attached figures may not show the various ways in which the disclosed processes can be used in conjunction with other processes. Additionally, the description sometimes uses terms like “provide” or “achieve” to describe the disclosed processes. These terms are high-level abstractions of the actual operations that are performed. The actual operations that correspond to these terms can vary depending on the particular implementation and are readily discernible by one of ordinary skill in the art.

The descriptions of the various embodiments of the present disclosure have been presented for purposes of illustration but are not intended to be exhaustive or limited to the embodiments disclosed. Many modifications and variations will be apparent to those of ordinary skill in the art without departing from the scope and spirit of the described embodiments. The terminology used herein was chosen to explain the principles of the embodiments, the practical application or technical improvement over technologies found in the marketplace, or to enable others of ordinary skill in the art to understand the embodiments disclosed herein.

What is claimed is:

1. An apparatus comprising:
a stack of a plurality of substrates, wherein the stack includes a plurality of channels extending therethrough, wherein the plurality of channels are configured to allow air to flow therethrough;
a plurality of dynamic random-access memory (DRAM) chips, wherein respective ones of the plurality of DRAM chips are attached to one of the plurality of substrates and located within one of the plurality of channels;
a plurality of processor chips located on an outer surface of the stack; and
a plurality of wires electrically connecting the plurality of DRAM chips to the plurality of processor chips.

2. The apparatus of claim 1, wherein the plurality of substrates are glass substrates.

3. The apparatus of claim 1, wherein the processor chips are logic chips.

4. The apparatus of claim 1, wherein the stack is arranged on its side, wherein the plurality of substrates extend vertically within the stack.

5. The apparatus of claim 1, wherein the plurality of wires extend vertically from the plurality of DRAM chips to the plurality of processor chips.

6. The apparatus of claim 1, further comprising:
a plurality of connections located on the outer surface of the stack and configured to electrically connect the plurality of processor chips to the plurality of wires.

7. A system for thermal management, the system comprising:
an integrated circuit (IC) package including:
a stack of a plurality of substrates, wherein the stack includes a plurality of channels extending therethrough, wherein the plurality of channels are configured to allow air to flow therethrough,
a plurality of dynamic random-access memory (DRAM) chips, wherein respective ones of the plurality of DRAM chips are attached to one of the plurality of substrates and located within one of the plurality of channels,
a plurality of processor chips located on an outer surface of the stack, and
a plurality of wires electrically connecting the plurality of DRAM chips to the plurality of processor chips; and
at least one heat dissipating device located adjacent at least one side of the IC package.

8. The system of claim 7, further comprising:
an apparatus adapted to force air through the plurality of channels.

9. The system of claim 7, wherein the at least one heat dissipating device is a heat sink.

10. The system of claim 7, wherein the plurality of substrates are glass substrates.

11. The system of claim 7, wherein the processor chips are logic chips.

12. The system of claim 7, wherein the stack is arranged on its side, wherein the plurality of substrates extend vertically within the stack.

13. The system of claim 7, wherein the plurality of wires extend vertically from the plurality of DRAM chips to the plurality of processor chips.

14. The system of claim 7, wherein the IC package further includes:
a plurality of connections located on the outer surface of the stack and configured to electrically connect the plurality of processor chips to the plurality of wires.

15. A method of fabricating an integrated circuit (IC) package, the method comprising:
providing a plurality of substrates, wherein the plurality of substrates have a first side and a second side;
forming a plurality of wires within the first side of the plurality of substrates;
forming trenches within the second side of the plurality of substrates;
attaching a plurality of dynamic random-access memory (DRAM) chips to the plurality of wires on the first side of the plurality of substrates;
stacking the plurality of substrates such that the DRAM chips on one of the plurality of substrates is located within the trenches on another adjacent one of the plurality of substrates in order to form a plurality of cooling channels around the plurality of DRAM chips adapted to provide air flow to the plurality of DRAM chips within a stack formed by the stacking;
attaching a plurality of processor chips to an outer surface of the stack; and
electrically connecting the plurality of processor chips to the plurality of DRAM chips.

16. The method of claim 15, wherein the plurality of substrates are glass substrates.

17. The method of claim 15, further comprising:
placing the stack on its side, wherein the plurality of substrates extend vertically within the stack,
wherein the plurality of processor chips are attached to a top side or a bottom side of the stack.

18. The method of claim 15, wherein the processor chips are logic chips.

19. The method of claim 15, wherein the plurality of wires extend vertically from the plurality of DRAM chips to the plurality of processor chips.

20. The method of claim 15, wherein a plurality of connections located on the outer surface of the stack are configured to electrically connect the plurality of processor chips to the plurality of wires and thereby to the plurality of DRAM chips.
